(19) United States
(12) Patent Application Publication
(10) Pub. No.: US 2013/0087454 A1
(43) Pub. Date: Apr. 11, 2013

(54) Magnetic Material Sputtering Target Provided with Groove in Rear Face of Target

(71) Applicant: Atsushi Sato, Ibaraki (JP)

(72) Inventor: Atsushi Sato, Ibaraki (JP)

(73) Assignee: JX NIPPON MINING & METALS CORPORATION, Tokyo (JP)

(21) Appl. No.: 13/703,958

(22) PCT Filed: Jun. 9, 2011
(86) PCT No.: PCT/JP2011/063216

§ 371 Date: Dec. 13, 2012

(30) Foreign Application Priority Data
Jul. 23, 2010 (JP) 2010-166086

(51) Int. Cl. C23C 14/34

(52) U.S. Cl. CPC C23C 14/3407
USPC 204/298.13

(57) ABSTRACT

Provided is a disk-shaped magnetic material sputtering target having a thickness of 1 to 10 mm, wherein the magnetic material sputtering target includes, on a rear surface thereof, at least one circular groove having a width of 5 to 20 mm and a depth of 0.1 to 3.0 mm centered around a center of the disk-shaped target, spacing of the respective grooves is 10 mm or more, and a non-magnetic material having a thermal conductivity of 20 W/m·K or more is embedded in the groove. The pass through flux density is increased in order to eliminate the defects that occur in the target of a magnetic material, the sputtering efficiency is improved by increasing the spread of plasma and improving the deposition rate, and the usage efficiency of the magnetic material target is additionally improved by inhibiting local erosion and causing the erosion on the target surface to be uniform.

### TECHNICAL FIELD

The present invention relates to a magnetic body target for use in a magnetron sputtering device, and particularly relates to a magnetic body target capable of improving the pass through flux density and enabling stable discharge

### BACKGROUND ART

Generally, the sputtering method is widely used as the method of forming a magnetic body thin film. There are various types of sputtering devices, and in the deposition of the magnetic body film, a magnetron sputtering device comprising a DC power supply is widely used for its high productivity. The sputtering method is a method in which a substrate as the positive electrode and a target as the negative electrode are caused to face each other, and a high voltage is applied between the substrate and the target in an inert gas atmosphere so as to generate an electric field.

Here, the inert gas is ionized and plasma made of electrons and positive ions is formed. When the positive ions in the plasma collide with the surface of the target (negative electrode), the atoms configuring the target are sputtered, and the sputtered atoms adhere to the opposing substrate surface and thereby form a film; this sequence of processes is taken using the principle that the material configuring the target is deposited on the substrate.

The magnetron sputtering method is a method of performing sputtering by setting a magnet on the rear side of the target and generating a magnetic field to the target surface in a direction that is perpendicular to the electric field. It is capable of achieving the stabilization and speed-up of the plasma in the crossed electromagnetic field space and increasing the sputtering rate.

Nevertheless, when the target is a magnetic material, the magnetron sputtering method entails the following drawbacks; specifically, since the pass through flux density is small (magnetic permeability is large), the spread of plasma decreases, causing the deposition rate to decrease and the sputtering efficiency to deteriorate and, since local erosion will advance, erosion of the target surface becomes uneven. Moreover, there is a problem in that the usage efficiency is considerably inferior in comparison to a non-magnetic material target, since the locally eroded portion determines the life of the target.

A conceptual diagram of the magnetic permeability (pass through flux density) in the case of using a non-magnetic material target and a ferromagnetic material target in the magnetron sputtering method is shown in FIG. 1. As shown in FIG. 1, when the magnetic permeability is small, in other word, when the pass through flux density is large, the magnetic flux density of the target surface will increase. Consequently, plasma will spread extensively, and the sputtering efficiency will increase due to the improved deposition rate and sputtering under low pressure.

Meanwhile, when the magnetic permeability is large, in other word, when the pass through flux density is small, the magnetic flux density of the target surface will decrease. Since the magnetic field lines become locally focused on the target surface pursuant to the advancement of sputtering, the erosion area is small, and only that portion is sputtered. That is, erosion of the target surface becomes uneven.

In light of the foregoing problems, conventional technologies have made the following improvements. For example, Patent Document 1 discloses a magnetron-type sputtering target which enables a magnetic body target to allow magnetic field lines to sufficiently pass through and be used for a long period of time. Specifically, disclosed is a magnetron-type sputtering target including a magnetic field generation means below the target mounting table, wherein sputtering is performed by generating a magnetic field which intersects with the electric field formed between the substrate and the magnetic body target. This magnetron-type sputtering target comprises a target body made of a magnetic body having a concave part at the location where the magnetic field lines generated by the magnetic field generation means pass through in a state of being mounted on the target mounting table, and a non-magnetic member embedded in the concave part of the target body. As the non-magnetic member to be embedded in the concave part, Al or SiO₂ is used.

While the technology of Patent Document 1 is considered to be basically effective, the position of the concave part is limited to the center and edge of the target as illustrated in the diagram, and when the embedded material is SiO₂, the thermal conductivity is low. Thus, it cannot be said that this is a structure which enables the improvement of the usage efficiency of the overall magnetic material target, but it can be said that additional improvement is required.

Even when the embedded material is Al, there is an advantage in that the thermal conductivity is high, however, it is necessary to devise the shape of the concave part (groove) in order to additionally increase the pass through flux density and improve the usage efficiency of the target. Here, it cannot be said that Patent Document 1 shows any special means of achieving improvement.

Patent Document 2 describes a sputtering target made of a magnetic body material such as cobalt, aiming for longer operating life. Specifically, since this sputtering target includes a first portion and a second portion that is thicker than the first portion (thickness of the first portion is approximately 1 mm and thickness of the second portion is 5 mm or more), the cumulative total value of the strength of the permeating magnetic field per a given length of time becomes greater with the first portion than the second portion. Thus, the magnetic field is caused to permeate the first portion, while the generation of a parallel magnetic field is promoted at the second portion.

The portion (first portion) in which the thickness of the target is reduced is dealt with by increasing the thickness of the backing plate. As with Patent Document 1, it cannot be said that Patent Document 2 has a structure which enables the improvement of the usage efficiency of the overall magnetic material target merely by adjusting the thinness or thickness of the target, and it can be said that additional improvement is required.

Patent Document 3 refers to a ferromagnetic body sputtering target. It aims to improve the usage efficiency and achieve a longer operating life, and inhibits local wear by providing parallel grooves in advance to either side of the area that is most easily subject to erosion, and thereby improves the usage efficiency of the target. As the target, used is a ferromagnetic body (specifically, elementary metal such as Fe, Co, or Ni, or the alloy thereof; rare earth metal such as Gd, Tb, Dy, Ho, Et, or Tm, Cu₂MnAl (Heusler alloy), MnAl, MnBi, etc.) or a ferrimagnetic body (ferrite such as magnetite and garnet).

Width of the grooves is 3 to 30 mm, depth of the grooves is 1 to 20 mm, and spacing between the grooves is 10 to 100 mm. Patent Document 3 requires the processing of the target surface (sputtered surface) and is of a special form and, as with Patent Document 1, it cannot be said that Patent Document 3 has a structure which enables the improvement of the usage efficiency of the overall magnetic material target, and it can be said that additional improvement is required.

Patent Document 4 describes a magnetron cathode structure of a magnetron cathode in which a backing plate is mounted on a magnetron made of a center magnet and a peripheral magnet which surrounds the center magnet, and a target is supported on the backing plate, wherein a soft magnetic yoke for guiding the magnetic field from the magnetron is embedded in the backing plate and/or the target, and, with the yoke that is disposed on the center magnet, the outer diameter of the upper face thereof is made to be smaller than the outer diameter of the center magnet, and/or with the yoke disposed on the peripheral magnet, the anode-cathode distance of the center magnet and the peripheral magnet is broadened.

In the foregoing case, the yoke disposed on the peripheral magnet is unique, and it cannot be said that Patent Document 4 has a structure which enables the improvement of the usage efficiency of the overall magnetic material target, and it can be said that additional improvement is required.

Moreover, Patent Document 5 proposes a magnetron sputtering device in which an annular groove is formed on the sputtered face of the target or a plurality of annular convex parts and annular grooves are formed on the non-sputtered face when the target is a thick magnetic body or ferromagnetic body.

In the foregoing case, while Patent Document 5 aims to increase the magnetic leakage field, there is a drawback in that the target structure is complex and that the production thereof is complicated since the target has a structure where concave parts and convex parts are respectively formed on the front face and rear face of the target.

Since at least two annular edge parts are formed for the annular grooves provided on the sputtered surface, possibly a problem of unevenness of deposition caused by such edge parts will arise.
[Patent Document 1] Japanese Patent No. 3063169
[Patent Document 2] Japanese Unexamined Patent Application Publication No. 2003-138372
[Patent Document 3] Japanese Unexamined Patent Application Publication No. H11-193457
[Patent Document 4] Japanese Unexamined Patent Application Publication No. H02-205673
[Patent Document 5] Japanese Unexamined Patent Application Publication No. 2010-222698

### SUMMARY OF THE INVENTION

### Problems to be Solved by the Invention

The present invention provides a magnetic material sputtering target that is suitable for magnetron sputtering capable of achieving the stabilization and speed-up of the plasma in the crossed electromagnetic field space and increasing the sputtering rate by performing sputtering upon setting a magnet on the rear side of the target and generating a magnetic field on the target surface in a direction that is perpendicular to the electric field. In order to eliminate the defects that occur with the target of a magnetic material, an object of this invention is to increase the pass through flux density, improve the sputtering efficiency by increasing the spread of plasma and improving the deposition rate, and additionally improve the usage efficiency of the magnetic material target by inhibiting local erosion and causing the erosion on the target surface to be uniform.

### Means for Solving the Problems

As a solution for the foregoing problems, as a result of intense study, the present inventors discovered that the following can be achieved by providing a groove on the rear surface of the target and devising the shape and arrangement of the groove and the filler to be embedded in the groove: it is possible to increase the pass through flux density and thereby increase the spread of plasma, improve the deposition rate and increase the sputtering efficiency as well as inhibit local erosion, cause the erosion of the target surface to be uniform, and thereby improve the usage efficiency of the magnetic material target.

Based on the discovery, the present invention provides the following invention.

1) A disk-shaped magnetic material sputtering target having a thickness of 1 to 10 mm, wherein the magnetic material sputtering target includes, on a rear surface thereof, at least one circular groove having a width of 5 to 20 mm and a depth of 0.1 to 3.0 mm centered around a center of the disk-shaped target, spacing of the respective grooves is 10 mm or more, and a non-magnetic material having a thermal conductivity of 20 W/m·K or more is embedded in the groove.

The foregoing circular groove is a round groove demarcated with the center of the disk-shaped (discoid) target as the core, and while one circular groove may be provided, a plurality of those may also be provided. If there are two or more of the foregoing circular grooves, the respective circular grooves mutually become “concentric circular grooves”. The ensuing explanation is described by using the term “concentric circular “grooves” or abbreviating the term to “grooves” as needed. The circular groove is formed between the center of the disk-shaped (discoid) target and the round outer edge.

2) The magnetic material sputtering target according to 1) above, wherein a cross section shape of the groove is a U-shape, a V-shape or a concave shape.
3) The magnetic material sputtering target according to 1) or 2) above, wherein the non-magnetic material embedded in the groove is an elementary metal of Ti, Cu, In, Al, Ag, or Zn, or an alloy having the elementary metal as its main component.
4) The magnetic material sputtering target according to any one of 1) to 3) above, wherein a saturated magnetization density of the target exceeds 2000 G (gauss), and a maximum magnetic permeability μmax of the target exceeds 10.
5) The magnetic material sputtering target according to any one of 1) to 4) above, wherein the magnetic material target is made of a ferromagnetic material of an element of one or more components selected from Co, Fe, Ni and Gd or an alloy having the element as its main component.
6) A magnetic material sputtering target as a sintered compact target in which one or more types of non-magnetic materials selected from oxide, carbide, nitride, carbonitride, and carbon are dispersed in the ferromagnetic material according to 5) above.
7) The magnetic material sputtering target according to 5) or 6) above, wherein the magnetic material sputtering target contains one or more elements selected from Cr, B, Pt, Ru, Ti, V, Mn, Zr, Nb, Mo, Ta, W, and Si in an amount of 0.5 at % or more and 50 at % or less.

### Effect of the Invention

The sputtering target of the present invention can provide a magnetic material sputtering target that is suitable for magnetron sputtering and yields superior effects of being able to increase the pass through flux density and thereby increase the spread of plasma, improve the deposition rate and increase the sputtering efficiency as well as inhibit local erosion, cause the erosion of the target surface to be uniform, and thereby improve the usage efficiency of the magnetic material target.

### BRIEF DESCRIPTION OF THE DRAWINGS

FIG. 1 is a conceptual diagram of the magnetic permeability (pass through flux density) in the case of using a non-magnetic material target and a ferromagnetic material target in the magnetron sputtering method.

FIG. 2 is a diagram showing the relationship of the distance from the target center and the erosion depth shown in Comparative Example 1.

FIG. 3 is a diagram showing the relationship of the distance from the target center and the erosion depth shown in Example 1.

FIG. 4 is a diagram showing an example of forming a groove on the magnetic material sputtering target and embedding a non-magnetic material in the groove.

### DETAILED DESCRIPTION OF THE INVENTION

The magnetic material sputtering target of the present invention is a disk-shaped (discoid) target in which a groove is formed on the rear surface of the target. While the groove is desirably formed at the portion that did not erode easily, since the position of the groove depends on the magnetron sputtering device, it would not be wise to fix the position of the groove.

Rather, the magnetic material target needs to be applicable far and wide so as not to be influenced by the type of magnetron sputtering device. If the magnetron sputtering device is fixed (specified) and the portion that does not erode easily is known in advance, it would obviously be preferable to form the groove at that position.

With the magnetic material sputtering target of the present invention, the thickness of the disk-shaped target can be 1 to 10 mm; however, the thickness implies the preferred target thickness, and it should be easy to understand that effects can still be yielded with a magnetic material sputtering target having a greater thickness.

The groove formed on the rear surface of the magnetic material sputtering target of the present invention includes at least one circular groove (round groove) having a width of 5 to 20 mm and a depth of 0.1 to 3.0 mm. This circular groove is a round groove demarcated with the center of the disk-shaped target as the core, and each groove is formed as a concentric circular groove when there are two or more circular grooves.

When there are two concentric circular grooves, the spacing between the respective concentric circular grooves is 10 mm or more. No groove is required at the center part of the disk-shaped target.

There is no need to form the foregoing circular groove or concentric circular groove at the center part or edge part of the target. As described above, since the thickness of the target is within the range of 1 to 10 mm, the depth needs to be adjusted according to the target thickness. The groove width can be adjusted to be 5 to 20 mm depending on the number of individual circular grooves.

When increasing the individual circular grooves, the width of the respective groove may be reduced. The thickness and width of the target may be arbitrarily adjusted depending on the type of magnetic material target.

The reason why the groove depth is made to be 3 mm or less is because, if it is greater than 3 mm, while this will also depend on the material and thickness of the target, the target strength of the groove portion will deteriorate and cause the thermal expansion of the target, and it is likely that problems such as the cracking of the target will arise due to such thermal expansion.

Moreover, if the groove depth is smaller than 0.1 mm, the improvement effect of the pass through flux density is hardly yielded. Hence, the groove depth needs to be 0.1 mm or more.

Moreover, the groove width is desirably adjusted to be 5 to 20 mm in many cases, while this will also depend on the shape of erosion. If the groove width is less than 5 mm, the improvement effect of the pass through flux density is hardly yielded, and, if the groove width is greater than 20 mm, there is a problem in that the target may become warped upon forming the groove on the target.

While the spacing between the grooves will depend on the size of the target, from the perspective of securing the target strength, the spacing between the grooves is 10 mm or more, and, with the size (diameter of 165.1 mm) of the target in the present case, the spacing between the grooves is 100 mm or less at maximum.

In addition, the present invention has the following requirement; namely, a non-magnetic material having a thermal conductivity of 20 W/m·K or more needs to be embedded in the respective grooves. The term “embed” may mean to fit a solid non-magnetic material into the groove or pouring a melted non-magnetic material into the groove and subsequently solidifying the same. Moreover, it is also possible to closely attach a solid non-magnetic material to the groove, applying pressure to the extent that plastic deformation will not occur under the temperature condition below the melting point, and use the diffused atoms arising between the bonding surfaces in order to bond the solid non-magnetic material and the groove. The foregoing “embed” covers all of the foregoing examples.

Since heat is generated from the plasma during sputtering, the backing plate plays the role of eliminating such heat. The thermal conductivity of the backing plate being 20 W/m·K or more yields an efficient heat elimination effect.

The cross section shape of the groove of the magnetic material sputtering target may be a U-shape, a V-shape or a concave shape. Since these grooves are formed by cutting the prepared target using a lathe or the like, it could be said that the shapes such as a U-shape, a V-shape or a concave shape, can be produced easily. However, it should be easy to understand that the cross section shape of the groove of the magnetic material sputtering target is not limited to the foregoing shapes. In other words, the present invention covers these shapes and their equivalents.

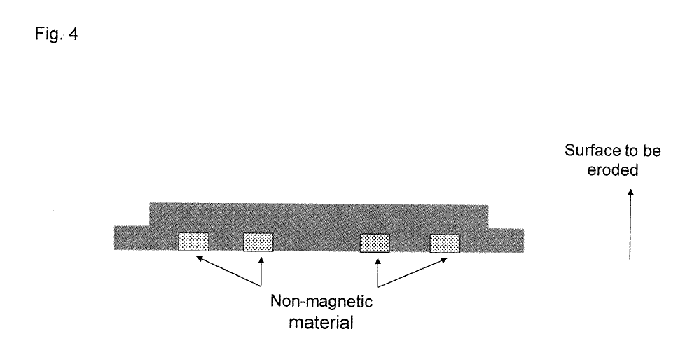

An example of a groove formed on a magnetic material sputtering target is shown in FIG. 4. FIG. 4 is a cross section of the magnetic material sputtering target, and the grove formed on the target in this case has a cross section shape of a concave shape. FIG. 4 shows a state where a non-magnetic material is embedded in the groove.

Desirably, the non-magnetic material embedded in the groove is an elementary metal of Ti, Cu, In, Al, Ag, or Zn, or an alloy having the elementary metal as its main component. This is because, not only are the foregoing elements a non-magnetic material, they also possess superior thermal conductivity.

In this respect, it would not be wise to use, for example, an oxide or the like even if it is a non-magnetic material. This is because the thermal conductivity is inferior.

As the non-magnetic material to be embedded, any material having a thermal conductivity that is higher than the material of the magnetic material target will suffice, and Co—Cr alloy and the like may also be used.

Upon performing deposition using a magnetron sputtering method, it is particularly effective when the saturated magnetization density of the target exceeds 2000 G (gauss), and the maximum magnetic permeability μmax exceeds 10. Moreover, the magnetic material target is preferably made of a ferromagnetic material of an element of one or more components selected from Co, Fe, Ni and Gd or an alloy having the element as its main component.

It should be easy to understand that a sintered compact target in which non-magnetic materials selected from oxide, carbide, nitride, carbonitride, and carbon are dispersed in the ferromagnetic material is also effective. In addition, the foregoing magnetic material sputtering target preferably contains one or more elements selected from Cr, B, Pt, Ru, Ti, V, Mn, Zr, Nb, Mo, Ta, W, and Si in an amount of 0.5 at % or more and 50 at % or less.

### EXAMPLES

The present invention is now explained based on the Examples and the Comparative Examples. Note that these Examples are illustrative only, and the present invention shall not be limited to these Examples in any way. In other words, this invention is limited only by the scope of claims indicated below, and covers the various modes other than the Examples contained in the present invention.

### Common Subject Matters of Examples 1 to 4 and Comparative Examples 1 and 2

A disk-shaped target having a target composition of 69 Co-6 Cr-15 Pt-10 SiO₂ (mol %), and a size of a diameter of 165.1 mm and a thickness of 6.35 mm was prepared. The maximum magnetic permeability of the mill ends of this target measured via a B-H tracer was 18, and the saturated magnetization density was 7300 G (gauss).

Subsequently, the pass through flux density was measured according to ASTMF2086-01 (Standard Test Method for Pass Through Flux of Circular Magnetic Sputtering Targets, Method 2). While details of the measuring procedures are omitted, the center of the target was fixed, the pass through flux density obtained by rotating and measuring the disk-shaped target at 0 degrees, 30 degrees, 60 degrees, 90 degrees, and 120 degrees was divided by the value of the reference field defined in ASTM, and multiplied by 100.

The results of averaging the foregoing five points are indicated in the Tables as the average pass through flux density (%). Subsequently, this target was sputtered with a magnetron sputtering device, discharged at 50 kWhr, and the shape of the erosion was measured.

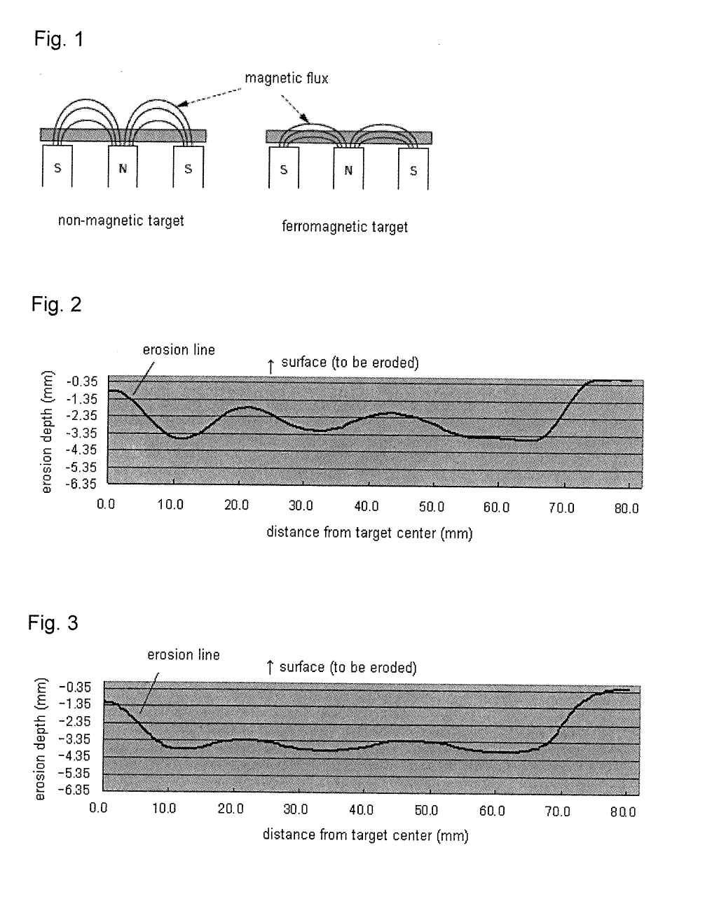

FIG. 2 shows a target in which a circular groove is not formed on the rear surface, and is a representative diagram showing the erosion line upon viewing the target from the cross section in the thickness direction including the target center, and FIG. 3 shows a target in which a circular groove is formed on the rear surface, and is a representative diagram showing the erosion line upon viewing the target from the cross section in the thickness direction including the target center. These diagrams are now explained in detail in the ensuing explanation.

### Comparative Example 1

Subsequently, a plurality of targets having the foregoing component composition was prepared. Here, a circular groove or concentric circular grooves were not formed at all. Consequently, the average pass through flux density was 39.1%, and the sputtering efficiency was also low. The results are shown in Table 1.

The state of erosion (erosion line) from the center (0.00 mm) of the target of Comparative Example 1 to near the outer periphery of the target (distance from center: 80.0 mm) is shown in FIG. 2. As evident from FIG. 2, there is not much erosion at the center part and outer edge part of the target, while the ruggedness of the erosion line between the center part and the outer peripheral part is severe, and it can be seen that there is much variation in the level of erosion.

Accordingly, with this disk-shaped target, the pass through flux density was low and the usage efficiency of the overall target was inferior.

### Comparative Example 2

Subsequently, a plurality of targets having the foregoing component composition was prepared, and two concentric circular grooves were provided to the areas that were not eroded easily in FIG. 2 (area with shallow erosion non-erosion area). The position of the grooves and the shape of the grooves are as shown in Table 1. Note that no material was embedded in the groove in Comparative Example 2.

The two grooves were made to be the same shape. The average pass through flux density in this case was compared to the case (Comparative Example 1) without any grooves described in Table 1, and it was confirmed that the average pass through flux density had improved. Nevertheless, when the target was discharged at 10 kWhr with a sputtering device, a scorched mark (oxidized pattern) was observed at the center of the groove portion of the target rear surface. With a sputtering device, normally a cooling plate comes into contact with the rear surface side of the target to provide mechanism for releasing the heat that is generated during sputtering. It is considered that the foregoing problem arose as a result of the target becoming heated due to the contact between the target and the cooling plate at the groove portion being insufficient.

TABLE 1

| | | Embedded | Average |
|---|---|---|---|
| | Position and Size of Groove | Material | PTF (%) |
| Comparative | No groove | None | 39.1% |
| Example 1 | | | |
| Comparative | Concave groove having width of 5 mm and depth of | None | 42.2% |
| Example 2 | 1.0 mm at positions of 20 mm and 45 mm from center | | |
| Example 1 | Concave groove having width of 5 mm and depth of | In | 42.1% |
| | 1.0 mm at positions of 20 mm and 45 mm from center | | |
| Example 2 | Concave groove having width of 10 mm and depth of | Cu | 45.9% |
| | 1.5 mm at positions of 20 mm and 45 mm from center | (oxygen-free | |
| | | copper) | |
| Example 3 | Concave groove having width of 10 mm and depth of | Al | 50.2% |
| | 2.0 mm at positions of 20 mm and 45 mm from center | | |
| Example 4 | Concave groove having width of 10 mm and depth of | Co—30 at % Cr | 54.0% |
| | 2.5 mm at positions of 20 mm and 45 mm from center | | |

### Example 1

In Example 1, a disk shaped target having a target composition of 69 Co-6 Cr-15 Pt-10 SiO₂ (mol %), and a size of a diameter of 165.1 mm and a thickness of 6.35 mm was used, a concave-shaped circular groove having a width of 5 mm and a depth of 1.0 mm was formed at the positions of 20 mm and 45 mm from the center, and molten In (thermal conductivity of 81 W/m·K) was poured into the grooves to fill the grooves.

Sputtering was performed using the target produced as described above. The conditions of these grooves and the average pass through flux density are shown in Table 1. Moreover, the state of erosion (erosion line) from the center (0.00 mm) of the target of Example 1 to near the outer periphery of the target (distance from center: 80.0 mm) is shown in FIG. 3.

As shown in FIG. 3, there is hardly any ruggedness of the erosion line between 10.0 mm to 70.0 mm from the center of the target, and this shows that the erosion of the target in the foregoing span was performed uniformly. Thus, the unused target portions will decrease, and the usage efficiency will increase. In comparison to Comparative Example 1 shown in FIG. 2, the difference in the erosion is evident.

In Example 1, it was confirmed that the average pass through flux density improved to 42.1%. As a result of actually sputtering this target, the problems encountered in Comparative Example 2 did not occur.

### Example 2

In Example 2, as with Example 1, a disk shaped target having a target composition of 69 Co-6 Cr-15 Pt-10 SiO₂ (mol %), and a size of a diameter of 165.1 mm and a thickness of 6.35 mm was used a concave-shaped circular groove having a width of 10 mm and a depth of 1.5 mm was formed at the positions of 20 mm and 45 mm from the center, and a ring made of oxygen-free copper (thermal conductivity of 391 W/m·K) of the same shape as the grooves was prepared, and fitted into the grooves. Sputtering was performed using the target produced as described above.

The conditions of these grooves and the average pass through flux density are shown in Table 1. In Example 2, it was confirmed that the average pass through flux density further improved to 45.9% in comparison to Example 1. As a result of actually sputtering this target, the problems encountered in Comparative Example 2 did not occur.

### Example 3

In Example 3, as with Example 1, a disk shaped target having a target composition of 69 Co-6 Cr-15 Pt-10 SiO₂ (mol %), and a size of a diameter of 165.1 mm and a thickness of 6.35 mm was used a concave-shaped circular groove having a width of 10 mm and a depth of 2.0 mm was formed at the positions of 20 mm and 45 mm from the center, and a ring made of Al (thermal conductivity of 237 W/m·K) of the same shape as the grooves was prepared, and fitted into the grooves. Sputtering was performed using the target produced as described above.

The conditions of these grooves and the average pass through flux density are shown in Table 1. In Example 3, it was confirmed that the average pass through flux density further improved to 50.2%, even when compared to Example 2. As a result of actually sputtering this target, the problems encountered in Comparative Example 2 did not occur.

### Example 4

In Example 4, as with Example 1, a disk shaped target having a target composition of 69 Co-6 Cr-15 Pt-10 SiO₂ (mol %), and a size of a diameter of 165.1 mm and a thickness of 6.35 mm was used a concave-shaped circular groove having a width of 10 mm and a depth of 2.5 mm was formed at the positions of 20 mm and 45 mm from the center, and a ring made of Co-30 at. % Cr alloy (thermal conductivity of 96 W/m·K) of the same shape as the grooves was prepared, and fitted into the grooves. Sputtering was performed using the target produced as described above.

The conditions of these grooves and the average pass through flux density are shown in Table 1. In Example 4, it was confirmed that the average pass through flux density further improved to 54.0%, even when compared to Example 3. As a result of actually sputtering this target, the problems encountered in Comparative Example 2 did not occur.

### Common Subject Matter of Examples 5 to 7 and Comparative Examples 3 and 4

A target base material having a composition of 85 Co-15 Cr (mol %) was prepared. The maximum magnetic permeability of this material measured via a B-H tracer was 25, and the saturated magnetization density was approximately 7000 G (gauss).

### Comparative Example 3

Subsequently, a disk-shaped target having a size of a diameter of 165.1 mm and a thickness of 6.35 mm was prepared from the foregoing base material. Upon measurement, the average pass through flux density of this target was 52.1%. While the average pass through flux density is higher in comparison to Comparative Example 1, this is considered to be a difference of the magnetic material itself.

### Comparative Example 4

Subsequently, a plurality of targets having the foregoing component composition was prepared, and three concentric circular grooves having a V-shaped cross section were provided to the areas that were anticipated as not eroded easily. The position of the grooves and the shape of the grooves are as shown in Table 2; namely, a V-shaped groove having a width of 5 mm and a depth of 1.0 mm was formed at the positions of 25 mm, 45 mm, and 75 mm from the center.

The average pass through flux density upon sputtering this target is shown in Table 2. In comparison to the case without any groove (Comparative Example 3), it was confirmed that the average pass through flux density improved to 56.0%.

Nevertheless, upon discharging this target at 1 kWhr with a sputtering device, the target had warped and the discharge stopped. It is considered that the foregoing problem arose as a result of the target becoming locally overheated due to the contact between the target and the cooling plate at the groove portion being insufficient.

TABLE 2

| | | Embedded | Average |
|---|---|---|---|
| | Position and Size of Groove | Material | PTF (%) |
| Comparative | No groove | None | 52.1% |
| Example 3 | | | |
| Comparative | V-shaped groove having width of 5 mm and depth of | None | 56.0% |
| Example 4 | 1.0 mm at positions of 25 mm and 45 mm and 75 mm | | |
| | from center | | |
| Example 5 | V-shaped groove having width of 5 mm and depth of | Ti | 56.0% |
| | 1.0 mm at positions of 25 mm and 45 mm and 75 mm | | |
| | from center | | |
| Example 6 | V-shaped groove having width of 10 mm and depth of | Ag | 59.7% |
| | 1.5 mm at positions of 25 mm and 45 mm and 75 mm | | |
| | from center | | |
| Example 7 | V-shaped groove having width of 10 mm and depth of | Zn | 65.4% |
| | 2.0 mm at positions of 25 mm and 45 mm and 75 mm | | |
| | from center | | |

### Example 5

In Example 5, a target material having a composition of 85 Co-15 Cr (mol %) was used, a plurality of targets having the foregoing component composition was prepared, and three concentric circular grooves having a V-shaped cross section were provided to the areas that were anticipated as not eroded easily. The position of the grooves and the shape of the grooves are as shown in Table 2; namely, a V-shaped groove having a width of 5 mm and a depth of 1.0 mm was formed at the positions of 25 mm, 45 mm, and 75 mm from the center.

In addition, a ring made of Ti (thermal conductivity of 21.9 W/m·K) of the same shape as the grooves was prepared, and fitted into the grooves by using In as the brazing filler metal. Sputtering was performed using the target produced as described above. The average pass through flux density in this case is shown in Table 2.

In Example 5, it was confirmed that the average pass through flux density improved to 56.0%. As a result of actually sputtering this target, the problems encountered in Comparative Example 4 did not occur.

### Example 6

In Example 6, as with Example 5, a target material having a composition of 85 Co-15 Cr (mol %) was used, a plurality of targets having the foregoing component composition was prepared, and three concentric circular grooves having a V-shaped cross section were provided to the areas that were anticipated as not eroded easily. The position of the grooves and the shape of the grooves are as shown in Table 2; namely, a V-shaped groove having a width of 10 mm and a depth of 1.5 mm was formed at the positions of 25 mm, 45 mm, and 75 mm from the center.

In addition, a ring made of Ag (thermal conductivity of 429 W/m·K) of the same shape as the grooves was prepared, and fitted into the grooves by using In as the brazing filler metal. Sputtering was performed using the target produced as described above. The average pass through flux density in this case is shown in Table 2.

In Example 6, it was confirmed that the average pass through flux density improved to 59.7% in comparison to Example 5. As a result of actually sputtering this target, the problems encountered in Comparative Example 4 did not occur.

### Example 7

In Example 7, as with Example 5, a target material having a composition of 85 Co-15 Cr (mol %) was used, a plurality of targets having the foregoing component composition was prepared, and three concentric circular grooves having a V-shaped cross section were provided to the areas that were anticipated as not eroded easily. The position of the grooves and the shape of the grooves are as shown in Table 2; namely, a V-shaped groove having a width of 10 mm and a depth of 2.0 mm was formed at the positions of 25 mm, 45 mm, and 75 mm from the center.

In addition, a ring made of Zn (thermal conductivity of 116 W/m·K) of the same shape as the grooves was prepared, and fitted into the grooves by using In as the brazing filler metal. Sputtering was performed using the target produced as described above. The average pass through flux density in this case is shown in Table 2.

In Example 7, it was confirmed that the average pass through flux density improved to 65.4% in comparison to Example 6. As a result of actually sputtering this target, the problems encountered in Comparative Example 4 did not occur.

As explained above, it is possible to increase the pass through flux density and thereby increase the spread of plasma, improve the deposition rate and increase the sputtering efficiency, as well as inhibit local erosion, cause the erosion of the target surface to be uniform, and thereby improve the usage efficiency of the magnetic material target.

While the foregoing Examples and Comparative Examples illustrated cases where the cross section of the groove is a concave-shaped and a V-shaped groove, but similar effects were yielded also with a U-shape groove. In other words, the same erosion line as Example 1 was observed.

With respect to the size, spacing and shape of the grooves formed on the target of the present invention and the type of material embedded in the grooves, similar effects were yielded so as long as the conditions were within the scope of the present invention.

While the Example illustrated cases of using Co, Cr, Pt, SiO₂-based magnetic materials, it has also been confirmed that similar effects can be yielded also with all ferromagnetic material sputtering targets made of an element of one or more components selected from Co, Fe, Ni and Gd or an alloy having the element as its main component.

### INDUSTRIAL APPLICABILITY

Since the magnetic material target of the present invention yields superior effects of being able to increase the pass through flux density and thereby increase the spread of plasma, improve the deposition rate and increase the sputtering efficiency as well as inhibit local erosion, cause the erosion of the target surface to be uniform, and thereby improve the usage efficiency of the magnetic material target, the present invention can provide a magnetic material sputtering target that is suitable for magnetron sputtering.

1: A disk-shaped magnetic material sputtering target having a thickness of 1 to 10 mm for use in a magnetron sputtering device, wherein the magnetic material sputtering target includes, on a rear surface thereof; at least two circular grooves having a width of 5 to 20 mm and a depth of 0.1 to 3.0 mm centered around a center of the disk-shaped target, spacing of the respective grooves is 10 mm or more, a cross section shape of the groove is a U-shape, a V-shape or a concave shape, and a non-magnetic material made of an elementary metal of Ti, Cu, In, Al, Ag, or Zn, or an alloy having the elementary metal as its main component and having a thermal conductivity of 20 W/m·K or more is embedded in the grooves.

2-3. (canceled)

4: The magnetic material sputtering target according to claim 1, wherein a saturated magnetization density of the target exceeds 2000 G (gauss), and a maximum magnetic permeability max of the target exceeds 10.

5: The magnetic material sputtering target according to claim 4, wherein the magnetic material target is made of a ferromagnetic material of an element of one or more components selected from Co, Fe, Ni and Gd or an alloy having the element as its main component.

6: A magnetic material sputtering target according to claim 5, wherein said sputtering target is a sintered compact target in which one or more types of non-magnetic materials selected from oxide, carbide, nitride, carbonitride, and carbon are dispersed in the ferromagnetic material.

7: The magnetic material sputtering target according to claim 6, wherein the magnetic material sputtering target contains one or more elements selected from Cr, B, Pt, Ru, Ti, V, Mn, Zr, Nb, Mo, Ta, W, and Si in an amount of 0.5 at % or more and 50 at % or less.

8: The magnetic material sputtering target according to claim 5, wherein the magnetic material sputtering target contains one or more elements selected from Cr, B, Pt, Ru, Ti, V, Mn, Zr, Nb, Mo, Ta, W, and Si in an amount of 0.5 at % or more and 50 at % or less.

9: The magnetic material sputtering target according to claim 1, wherein the magnetic material target is made of a ferromagnetic material of an element of one or more components selected from Co, Fe, Ni and Gd or an alloy having the element as its main component.

10: A magnetic material sputtering target according to claim 9, wherein said sputtering target is a sintered compact target in which one or more types of non-magnetic materials selected from oxide, carbide, nitride, carbonitride, and carbon are dispersed in the ferromagnetic material.

11: The magnetic material sputtering target according to claim 10, wherein the magnetic material sputtering target contains one or more elements selected from Cr, B, Pt, Ru, Ti, V, Mn, Zr, Nb, Mo, Ta, W, and Si in an amount of 0.5 at % or more and 50 at % or less.

12: The magnetic material sputtering target according to claim 9, wherein the magnetic material sputtering target contains one or more elements selected from Cr, B, Pt, Ru, Ti, V, Mn, Zr, Nb, Mo, Ta, W, and Si in an amount of 0.5 at % or more and 50 at % or less.
